(19) United States
(12) Patent Application Publication
(10) Pub. No.: US 2025/0098107 A1
(43) Pub. Date: Mar. 20, 2025

(54) CONDUCTOR MEMBER WITH COOLING STRUCTURE

(71) Applicant: Yazaki Corporation, Tokyo (JP)

(72) Inventors: Junya HIGASHI, Kakegawa-shi (JP); Hiroyuki Tanaka, Kakegawa-shi (JP); Kazuki Shirosaka, Kakegawa-shi (JP)

(73) Assignee: Yazaki Corporation, Tokyo (JP)

(21) Appl. No.: 18/804,691

(22) Filed: Aug. 14, 2024

(30) Foreign Application Priority Data
Sep. 20, 2023 (JP) 2023-152096

(51) Int. Cl. H05K 7/20; H01B 5/02

(52) U.S. Cl. CPC H05K 7/20254; H01B 5/02; H05K 7/2049

(57) ABSTRACT

A conductor member with cooling structure is characterized that it includes a conductor member formed of a conductive metal in a strip shape with one end side thereof being connected to a component terminal of a predetermined electrical/electronic member, and the other end side thereof being connected to an electrical connection target of the electrical/electronic member to be energized; a cooling pipe into which refrigerant flows; and a fixing wall as a wall formed of an insulation resin to which the conductor member together with the electrical/electronic member are fixed, and to which the cooling pipe is fixed such that the cooling pipe extends to be in contact with a connection portion of the conductor member connected with the component terminal.

### TECHNICAL FIELD

The present invention relates to a conductor member with cooling structure that connects component terminals of electrical and electronic components while performing cooling to itself.

### BACKGROUND ART

Conventionally, a conductor member with cooling structure adding a self-cooling function to a conductor member connecting component terminals of electrical and electronic components as the electrical connection targets is known (for example, see Patent Document 1). The conductor member with cooling structure according to Patent Document 1 has a configuration by using a conductive pipe as the conductor member and having both ends thereof to be crushed to form a connection portion with the component terminals of electrical and electronic components and the electrical connection targets. The electrical connection is performed by the conductive pipe itself, and the cooling is performed by the refrigerant flowing in the pipe.

### CITATION LIST

### Patent Documents

[Patent Document 1] JP 2018-018661A

### SUMMARY OF THE INVENTION

### Technical Problem

Here, according to the above-described conductor member with cooling structure using the conductive pipe, since both ends of the pipe are crushed to be used as the connection portion, such connection portion requires advanced molding technology which tends to increase manufacturing costs.

Accordingly, the present invention is focused on the above-described technical problem and an object of the present invention is to provide a conductor member with cooling structure which can perform the cooling while suppressing the manufacturing cost.

### Solution to Problem

In order to solve the above-identified problem, a conductor member with cooling structure is characterized by including a conductor member formed of a conductive metal in a strip shape with one end side thereof being connected to a component terminal of a predetermined electrical/electronic member, and the other end side thereof being connected to an electrical connection target of the electrical/electronic member to be energized; a cooling pipe into which refrigerant flows; and a fixing wall as a wall formed of an insulation resin to which the conductor member together with the electrical/electronic member are fixed, and to which the cooling pipe is fixed such that the cooling pipe extends to be in contact with a connection portion of the conductor member connected with the component terminal.

### Effect of the Invention

According to the above-described conductor member with cooling structure, it is possible to perform the cooling while suppressing the manufacturing costs.

### BRIEF DESCRIPTION OF THE DRAWINGS

FIG. 1 is a perspective view showing a conductor member with cooling structure according to a first embodiment.

FIG. 2 is a perspective view showing the conductor member with cooling structure shown in FIG. 1 by excluding the electrical and electronic component and the conductor member.

FIG. 3 is a planar view showing a connection location between the component terminal of the electrical and electronic component and the conductor member shown in FIG. 1 together with the cooling pipe in contact therewith.

FIG. 4 is a perspective view showing a conductor member with cooling structure according to a second embodiment by excluding the electrical and electronic component and the conductor member, similar to FIG. 2.

FIG. 5 is a planar view showing a connection location between the component terminal of the electrical and electronic component and the conductor member regarding the conductor member with cooling structure shown in FIG. 4 together with the cooling pipe in contact therewith, similar to FIG. 3.

### DESCRIPTION OF EMBODIMENTS

Hereinafter, an embodiment of a conductor member with cooling structure will be described. At first, a first embodiment will be described.

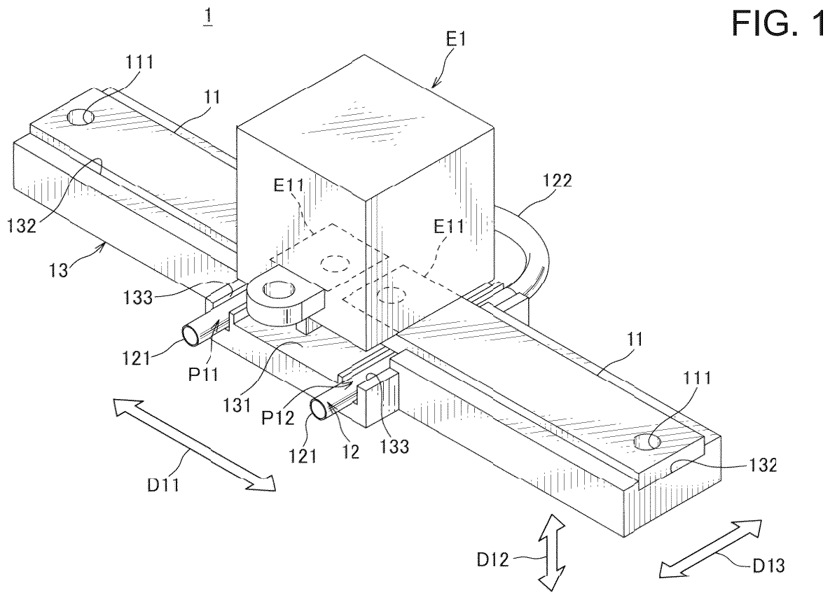

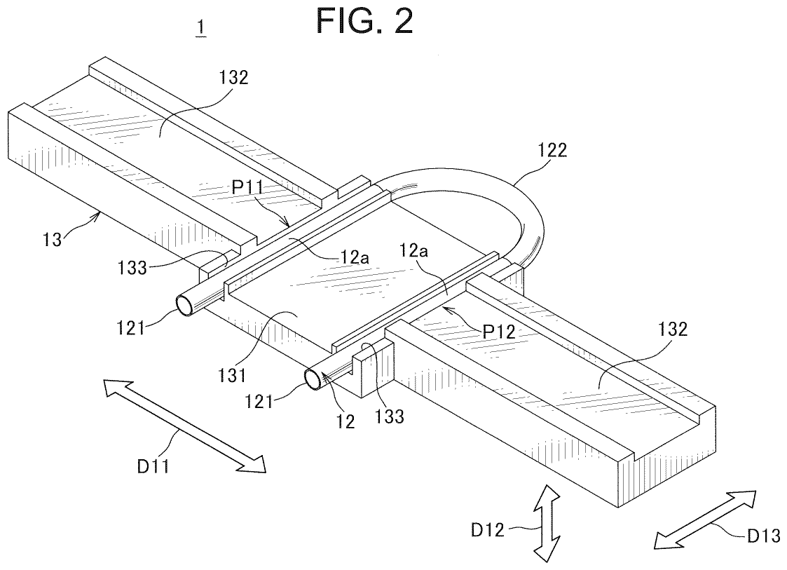

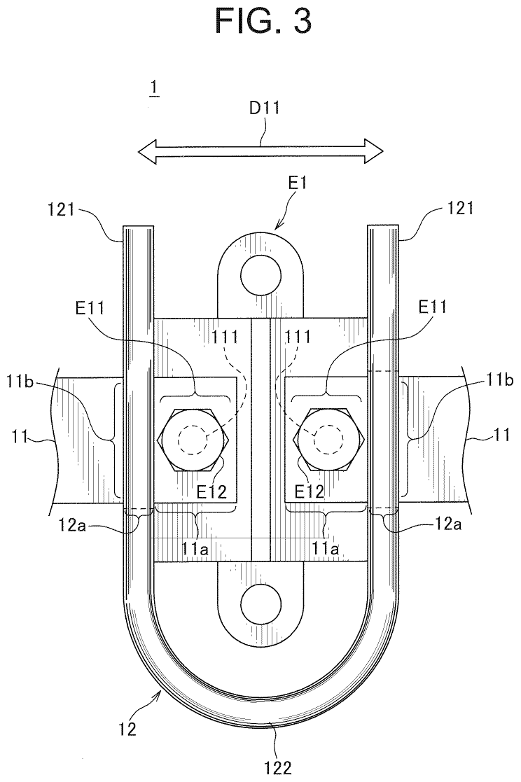

FIG. 1 is a perspective view showing a conductor member with cooling structure according to a first embodiment. FIG. 2 is a perspective view showing the conductor member with cooling structure shown in FIG. 1 by excluding the electrical and electronic component and the conductor member. Also, FIG. 3 is a planar view showing a connection location between the component terminal of the electrical and electronic component and the conductor member shown in FIG. 1 together with the cooling pipe in contact therewith.

A conductor member with cooling structure 1 according to the present embodiment is a member for connecting each of a pair of component terminals E11 in a relay as an electrical/electronic member E1 to an electrical connection target of this electrical/electronic member E1. The conductor member with cooling structure 1 includes a pair of conductor member 11 connected to the pair of component terminals E11 in one-to-one relationship, a single cooling pipe 12, and a fixing wall 13 on which this cooling pipe 12 is fixed.

The conductor member 11 is formed of a conductive metal such as copper and the like in a rectangular strip shape as an energized busbar with one end side being connected to the component terminal E11 of the electrical/electronic member E1 and the other end side being connected to an electrical connection target of the electrical/electronic member E1. The connections of the two end portions are performed by screw fastening, and a screw penetration hole 111 through which a screw for fastening E12 is provided in each end portion. The conductor members 11 are provided in a pair such that the conductor members 11 are connected with a pair of component terminals E11 in one-to-one relationship and each of the conductor members 11 extends in an arrangement direction D11 of the component terminal E11.

The cooling pipe 12 is formed by bending a round pipe into a U-shape in the middle thereof, and through which the refrigerant flows. According to the present embodiment, the water as a conductive fluid is used as the refrigerant. Also, as the cooling pipe 12, a conductive metal pipe is used. As an example of the metal pipe, a copper pipe and the like can be listed.

Also, both of a conductor-side contact surface 11b in the conductor member 11 that is in contact with the cooling pipe 12 and a pipe-side contact surface 12a in the cooling pipe 12 that is in contact with the conductor member 11 are applied with insulation processing by the insulation coating and the like.

The fixing wall 13 is a wall made of insulation resin to which the conductor member 11, together with the electrical/electronic member E1, are fixed, wherein the fixing wall 13 is a portion to which the cooling pipe 12 is fixed such that the cooling pipe 12 extends to be in contact with the connection portion 11a with the component terminal E11 in the conductor member 11. This fixing wall 13 becomes the wall portion configuring part of the device housing in which the conductor member 11 and the electrical/electronic member E1 are mounted.

In the fixing wall 13, a component facing portion 131 to which the pair of component terminals E11 in the electrical/electronic member E1 face via the connection portions 11a of the pair of conductor members 11, and a pair of conductor attachment grooves 132 into which the pair of conductor members 11 are received in one-to-one relationship to be attached are provided. The pair of conductor attachment grooves 132 are formed to extend from the component facing portion 131 in the arrangement direction D11 of the component terminals E11. Each conductor attachment groove 132 becomes a square groove with a thin bottom so as to receive approximately half of the rectangular strip-shaped conductor member 11 in a thickness direction D12 thereof. Then, a pair of piping grooves 133 into which the cooling pipe 12 is fitted so as to pass a position in contact with the connection portion 11a of the conductor member 11 are formed in the boundary portion between the component facing portion 131 and the pair of conductor attachment grooves 132.

The pair of piping grooves 133 become square grooves formed along a width direction D13 of the conductor member 11 such that a pair of arm portions 121 in the cooling pipe 12 bent in the U-shape extend to intersect the connection portions 11a of the pair of conductor members 11 in the width direction D13. The cooling pipe 12 is attached with a first contact position P11 at which one side of the pair of piping grooves 133 is in contact with one side of the pair of connection portions 11a, and a second contact position P12 at which the other side of the pair of piping grooves 133 is in contact with the other side of the pair of connection portions 11a. The cooling pipe 12 is fixed to the fixing wall 13 in a state in which a U-shaped bending portion 122 being bent between the first contact position P11 and the second contact position P12 is formed. Here, the fixing is carried out by adhering the cooling pipe 12 and the piping groove 133 with an adhesive, or by welding of melting a part of the pipe groove 133 of the fixing wall 13 made of insulation resin and then integrating it with the metal cooling pipe 12, and the like.

According to the conductor member with cooling structure 1 in the above-described first embodiment, regarding the conductor member 11 carrying out the conduction between the component terminal E11 of the electrical/electronic member E1 and the electrical connection target, it can be used without any additional machining regarding the cooling. Also, regarding the connection portion 11a in the conductor member 11 connected with the component terminal E11 that tends to generate a large amount of heat when energized, it is possible to effectively perform cooling by the cooling pipe 12 in which the refrigerant flows. In this manner, according to the conductor member with cooling structure 1 of the present embodiment, it is unnecessary to perform any additional machining with the conductor member 11 such that it is possible to perform the cooling by reducing the manufacturing costs.

Here, according to the present embodiment, the refrigerant is the water as the conductive fluid and the cooling pipe 12 is the conductive metal pipe such as the copper pipe or the like, wherein the insulation processing is applied to both of the conductor-side contact surface 11b and the pipe-side contact surface 12a. According to such a configuration, it is possible to prevent the component terminal E11 of the electrical/electronic member E1 and the connection portion 11a from being unintentionally short-circuited via the refrigerant and the cooling pipe 12, while using the general water, the copper pipe and the like as the refrigerant and the cooling pipe 12, respectively.

Also, according to the present embodiment, the piping groove 133 into which the cooling pipe 12 is fitted is formed in the fixing wall 13. According to such a configuration, since the cooling pipe 12 becomes the structure to be fitted into the piping groove 133, it is possible to fix the cooling pipe 12 without disturbing the fixing of the electrical/electronic member E11 and the conductor member 11 to the fixing wall 13. Also, by adopting such pipe-fitting structure, it is possible to miniaturize the conductor member with cooling structure 1.

Also, according to the present embodiment, the fixing wall 13 becomes the wall portion configuring a part of the device housing. According to such a configuration, the part of the device housing can be adopted as the fixing wall 13 of the cooling pipe 12 such that it is possible to further suppress the manufacturing costs when compared with the case in which the fixing wall is prepared as another member.

Also, according to the present embodiment, the conductor members 11 are provided in a pair so as to be connected to the pair of component terminals E11 in one-to-one relationship and extend in the arrangement direction D11 of the component terminal E11. Also, the cooling pipe 12 as a single pipe is fixed to the fixing wall 13 in the state of being bent from the first contact position P11 in contact with one side of the connection portion 11a to the second contact portion P12 in contact with the other side of the connection portion 11a. According to such a configuration, it is possible to effectively cool each of connection portions 11a of the pair of conductor members 11 connected to the pair of component terminals E11 in the electrical/electronic member E1 by the single cooling pipe 12.

According to the present embodiment, the cooling pipe 12 is bent in the U-shape between the first contact position P11 and the second contact position P12. According to such a configuration, the bending machining with respect to the single cooling pipe 12 can be carried out by the easy U-shape bending such that it is possible to further suppressing the manufacturing costs.

Hereinafter, a second embodiment will be described. The second embodiment is different from the first embodiment in the bending shape of the cooling pipe and the fixing structure of the cooling pipe in the fixing wall. Hereinafter, the second embodiment will be described by focusing on the differences with the first embodiment.

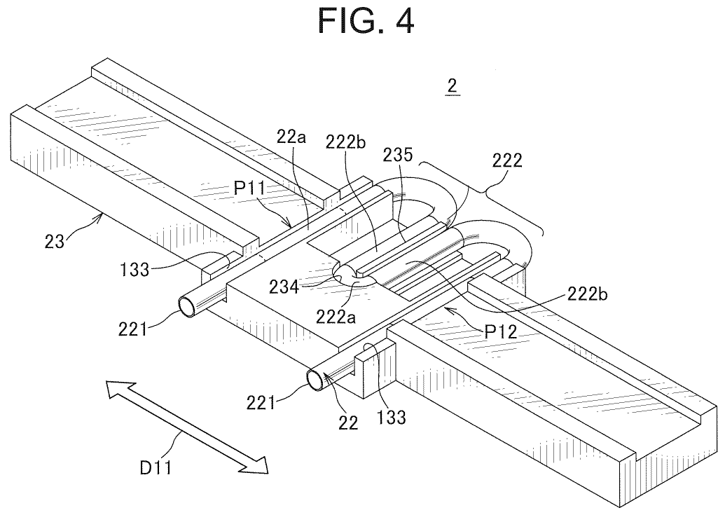

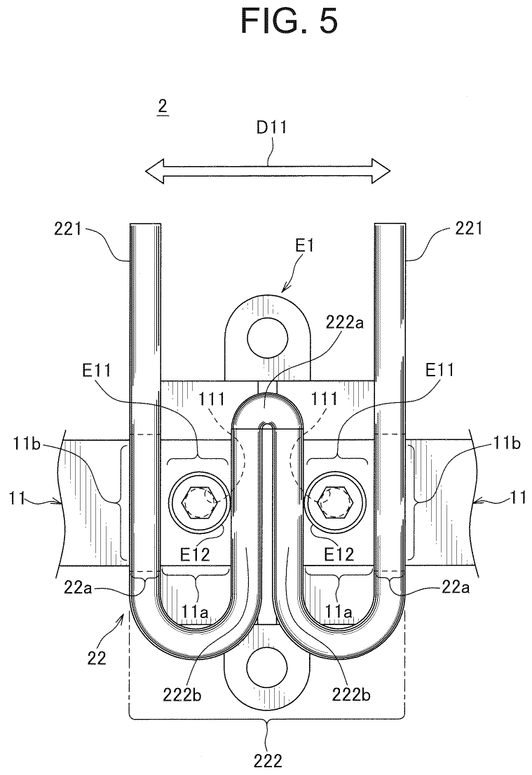

FIG. 4 is a perspective view showing a conductor member with cooling structure according to the second embodiment by excluding the electrical and electronic component and the conductor member, similar to FIG. 2. FIG. 5 is a planar view showing a connection location between the component terminal of the electrical and electronic component and the conductor member regarding the conductor member with cooling structure shown in FIG. 4 together with the cooling pipe in contact therewith, similar to FIG. 3. Also, in FIG. 4 and FIG. 5, regarding the configuration elements equivalent to the configuration elements according to the first embodiment as shown in FIG. 1 to FIG. 3, only the elements necessary to be described will be designated with the same reference signs as in FIG. 1 to FIG. 3, and the duplicate description with regard to such configuration elements will be omitted. Also, in FIG. 5, regarding the fastening screw of the conductor member 11, although the screw is shown with a screw head in a different shape when compared to FIG. 3, they are substantially the same elements and the same reference sign “E12” is designated to that in FIG. 3.

The point in which a conductor member with cooling structure 2 according to the second embodiment includes the pair of conductor members 11 being connected to the pair of component terminals E11 of the electrical/electronic member E1 in one-to-one relationship is the same with that according to the above-described first embodiment. However, according to the present embodiment, the shape of the single cooling pipe 22 in contact with the connection portions 11a of the pair of conductor members 11 and the fixing structure of this cooling pipe 22 in the fixing wall 23 are different from that according to the first embodiment.

In the cooling pipe 22, both of a portion at the first contact position P11 in contact with the connection portion 11a at one side and a portion at the second contact position P12 in contact with the connection portion 11a at the other side become an arm portion 221 extending in a straight-line shape. Then, a shape from the arm portion 221 at one side passing the first contact position P11 to the arm portion 221 at the other side passing the second contact position P12 is bent in a W-shape as shown below. The cooling pipe 22 at first comes into contact with the arm portion 221 at one side at the outside of an arrangement of a pair of screw penetration holes 111 in the connection portion 11a at one side at the first contact position P11, and then the cooling pipe 22 is bent toward the inside of the arrangement of the screw penetration holes 111 and folded at the inner side thereof. Furthermore, the cooling pipe 22 is folded toward the outside of the arrangement to come into contact with the arm portion 221 at one side at the outside of the arrangement in the connection portion 11a at the other side. The cooling pipe 22 is configured in a W-shaped bending shape by the pair of arm portions 221 passing the outside of the arrangement of the pair of screw penetration holes 111 and the bending portion 222 including the folded portion at the inner side of the arrangement.

The fixing structure of the cooling pipe 22 that is bent in this W-shape on the fixing wall 23 includes, similar to that in the first embodiment, the pair of piping grooves 133 into which the pair of arm portions 221 in the straight-line shape are fitted, a folded end portion retention groove 234, and a folded retention rib 235. The folded end portion retention groove 234 is a U-shaped groove portion into which the folded end portion 222a of the cooling pipe 22 at the inner side of the arrangement of the pair of screw penetration holes 111 are fitted for retaining the folded end portion 222a. The folded retention rib 235 is a rib inserted into a gap between a pair of straight pipe portions 222b extending in the straight-line shape from the folded end portion 222a that is retained by the folded end portion retention groove 234. This folded retention rib 235 is positioned with the folded end portion 222a and the pair of straight pipe portions 222b in the middle in the arrangement direction D11 of the pair of screw penetration holes 111 to retain these portions in cooperation with the folded end portion retention groove 234.

According to the conductor member with cooling structure 2 of the above-described embodiment 2, similar to the above-described first embodiment, any additional machining and the like are unnecessary for the conductor member 11, thus it is possible to perform the cooling while suppressing the manufacturing costs.

According to the present embodiment, the cooling pipe 22 is in the shape of being bent in the above-described W-shape. According to such a configuration, compared with the bending process with respect to the single cooling pipe 22 in the U-shape, it becomes complicated, however, it is possible to improve the cooling efficiency since the connection portion 11a of each conductor member 11 is cooled from the inside and the outside of the arrangement direction D11 of the screw penetration hole 111.

Also, the above-described first embodiment and the second embodiment are merely representative embodiments of the conductor member with cooling structure. The conductor member with cooling structure is not limited thereto and can be implemented with various modifications.

For example, according to the above-described embodiments, as an example of the conductor member with cooling structure, the conductor member with cooling structure 1, 2 for connecting each of the pair of component terminals E11 in the relay as the electrical/electronic member E1 as the electrical connection target is shown. However, the conductor member with cooling structure is not limited thereto, and the connected electrical/electronic member may be other electrical member other than the relay, or other electronic members.

Also, according to the above-described embodiment, as an example of the conductor member with cooling structure, the conductor member with cooling structure 1, 2 with a liquid cooling structure in which the water being the conductive liquid flows in the cooling pipe 12, 22 as the refrigerant is shown. However, the conductor member with cooling structure is not limited thereto, and the refrigerant may be non-conductive liquid, or air-cooling gas.

Also, according to the above-described embodiment, as an example of the conductor member with cooling structure, the conductor member with cooling structure 1, 2 including the pair of conductor members 11 is shown. However, the conductor member with cooling structure is not limited thereto, only one conductor member may be provided, and three or more than three conductor members may be provided.

Also, according to the above-described embodiment, as an example of the cooling pipe, the round cooling pipe 12, 22 that is configured of the metal pipe such as the copper pipe or the like having conductivity is shown. However, the cooling pipe is not limited thereto and may be configured of non-conductive metal, resin or the like, and regarding the shape thereof, square pipes, other polygonal type pipes and the like rather than the round pipe may be used. Also, in the case in which the cooling pipe is formed of the non-conductive metal, resin or the like, the insulation processing between the cooling pipe and the conductor member becomes unnecessary.

According to the above-described embodiment, as an example of the conductor member with cooling structure, the conductor member with cooling structure 1, 2 to which the insulation processing is applied is shown. That is, the insulation processing mentioned above is applied to both of the conductor-side contact surface 11b in the conductor member 11 and the pipe-side contact surfaces 12a, 22b in the cooling pipes 12, 22. However, the conductor member with cooling structure is not limited thereto, and the insulation processing may be applied to either one of the conductor-side contact surface of the conductor member or the pipe-side contact surface of the cooling pipe. Also, a range of the insulation processing is not merely limited to the conductor-side contact surface and the pipe-side contact surface, and the insulation processing may be applied to a wide range including the conductor-side contact surface in the conductor member, and the insulation processing may be applied to a wide range including the pipe-side contact surface in the cooling pipe.

Also, according to the above-described embodiment, as an example of the conductor member with cooling structure, the conductor member with cooling structure 1, 2 in which the insulation processing is applied to both of the conductor-side contact surface 11b and the pipe-side contact surface 12a, 22a is shown. However, the conductor member with cooling structure is not limited thereto, and it may adopt a pipe formed of non-conductive material such as the insulation resin as the cooling pipe without performing the above-described insulation processing. However, as described above, by applying the above-described insulation processing, the general water and the copper pipe can be adopted as the refrigerant and the cooling pipe 12, respectively.

Also, according to the above-described embodiment, as an example of the fixing wall, the fixing wall 13, 23 in which the piping groove 133 into which the cooling pipe 12, 22 is fitted, is shown. However, the fixing wall is not limited thereto, any suitable structure may be adopted as the fixing structure of the cooling pipe. However, due to the formation of the piping groove 133, as described above, it is possible to fix the cooling pipe 12, 22 without disturbing fixing the electrical/electronic member E11 and the conductor member 11 with respect to the fixing wall 13, 23, and thus it is possible to miniaturize the conductor member with cooling structure 1, 2.

Also, according to the above-described embodiment, as an example of the fixing wall, the fixing wall 13, 23 becoming the wall portion configured part of the device housing is shown. However, the fixing wall is not limited thereto, and the fixing wall may be provided as a separate member with respect to the device housing. However, as described above, by adopting part of the device housing as the fixing wall 13, 23 of the cooling pipe 12, 22, it is possible to further reduce the manufacturing costs.

Also, according to the above-described embodiment, as an example of the conductor member with cooling structure, the conductor member with cooling structure 1, 2 in which the single cooling pipe 12, 22 is bent in the middle so as to be in contact with the connection portion 11a of the pair of conductor members 11 and fixed to the fixing wall 13, 23 is shown. However, the conductor member with cooling structure is not limited thereto, for example, two cooling pipes in the straight-line shape being contact with the connection portions of the pair of conductor members in one-to-one relationship may be provided. However, according to the configuration of bending the single cooling pipe 12, 22 to make it to be in contact with the connection portion 11a of the pair of conductor members 11, as described above, it is possible to efficiently cool the connection portion 11a of the pair of conductor members 11 by the single cooling pipe 12.

Also, according to the above-described embodiment, as an example of the cooling pipe that is bent in the middle, the cooling pipe 12 being bent in the U-shape and the cooling pipe 22 being bent in the W-shape are shown. However, the bending shape of the cooling pipe is not limited to the U-shape and the W-shape, any bending shape may be adopted as long as it can contact and cool the connection portion of the pair of conductor members. However, according to the bending shape in the U-shape, it is possible to further suppress the manufacturing costs due to the ease of the bending processing, and according to the bending shape in the W-shape, as described above, each connection portion can be cooled from two directions so as to improve the cooling efficiency.

### REFERENCE SIGNS LIST

1,2 conductor member with cooling structure
11 conductor member
11a connection portion
11b conductor-side contact surface
12, 22 cooling pipe
12a, 22a pipe-side contact surface
13 fixing surface
111 screw penetration hole
121, 221 arm portion
122 U-shaped bending portion
131 component facing portion
132 conductor attachment groove
133 piping groove
222 bending portion
222a folded end portion
222b straight pipe portion
234 folded end retention groove
235 folded retention rib
D11 arrangement direction
D12 thickness direction
D13 width direction
E1 electrical/electronic member
E11 component terminal
E12 fastening screw
P11 first contact position
P12 second contact position

What is claimed is:

1. A conductor member with cooling structure, comprising:
a conductor member formed of a conductive metal in a strip shape with one end side thereof being connected to a component terminal of a predetermined electrical/electronic member, and the other end side thereof being connected to an electrical connection target of the electrical/electronic member to be energized;
a cooling pipe into which refrigerant flows; and
a fixing wall as a wall formed of an insulation resin to which the conductor member together with the electrical/electronic member are fixed, and to which the cooling pipe is fixed such that the cooling pipe extends to be in contact with a connection portion of the conductor member connected with the component terminal.

2. The conductor member with cooling structure according to claim 1,
wherein the refrigerant is a conductive fluid,
the cooling pipe is a metal pipe having conductivity, and
an insulative processing is applied to at least one of a conductor-side contact surface in the conductor member that is in contact with the cooling pipe or a pipe-side contact surface in the cooling pipe that is in contact with the conductor member.

3. The conductor member with cooling structure according to claim 1, wherein a piping groove into which the cooling pipe is fitted so as to pass a position in contact with the connection portion is formed.

4. The conductor member with cooling structure according to claim 1, wherein the fixing wall is a wall portion configuring part of a predetermined device housing.

5. The conductor member with cooling structure according to claim 1,
wherein a pair of component terminals are provided in the electrical/electronic member,
a pair of conductor members are provided such that the pair of component terminals are connected with the pair of conductor members in one-to-one relationship and each of the pair of conductor members extends in an arrangement direction of the component terminal, and
the cooling pipe is a single pipe partly fixed to the fixing wall so as to be in contact with the connection portion of each of the pair of conductor members, and the cooling pipe is fixed to the fixing wall in a state of being bent from a first contact position in contact with the connection portion at one side to a second contact position in contact with the connection portion at the other side.

6. The conductor member with cooling structure according to claim 5, wherein the cooling pipe is bent in a U-shape between the first contact position and the second contact position.

7. The conductor member with cooling structure according to claim 5,
wherein a screw penetration hole for screw fastening to the component terminal is formed in the connection portion of the conductor member,
the first contact position and the second contact position are provided to sandwich a pair of screw penetration holes therebetween in the arrangement direction, and
a shape of the cooling pipe from a portion at the first contact position to a portion at the second contact position is bent in a W-shape such that after the cooling pipe comes into contact with the outside of an arrangement of the pair of screw penetration holes in the connection portion at one side, the cooling pipe is bent toward an inside of the arrangement and folded at the inside thereof, and the cooling pipe is further folded toward the outside of the arrangement to come into contact with the outside of the arrangement in the connection portion at the other side.
